(19) United States
(12) Patent Application Publication
(10) Pub. No.: US 2025/0374560 A1
(43) Pub. Date: Dec. 4, 2025

(54) SEMICONDUCTOR DEVICE STRUCTURE AND METHOD OF MANUFACTURING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/742,098

(22) Filed: Jun. 13, 2024

Related U.S. Application Data
(62) Division of application No. 18/678,395, filed on May 30, 2024.

(51) Int. Cl. H10B 80/00; H01L 21/48; H01L 21/56; H01L 23/31; H01L 23/48; H01L 23/538; H01L 25/00; H01L 25/065

(52) U.S. Cl. CPC H10B 80/00; H01L 21/4857; H01L 21/568; H01L 23/3142; H01L 23/481; H01L 23/5383; H01L 23/5386; H01L 23/5389; H01L 25/0655; H01L 25/50

(57) ABSTRACT

A semiconductor device structure and method of manufacturing the same are provided. The semiconductor device structure includes an interposer and a first electronic component. The interposer includes a first semiconductor die and a second semiconductor die. The first semiconductor die includes a first cache memory and a first memory control circuit. The second semiconductor die includes a second cache memory and a second memory control circuit. The first electronic component is disposed on the interposer and is in communication with the first semiconductor die and the second semiconductor die. The first semiconductor die has at least one first air gap structure, or at least one first through via with non-uniform dimensions.

### CROSS-REFERENCE TO RELATED APPLICATION

This application is a divisional application of U.S. Non-Provisional application Ser. No. 18/678,395 filed May 30, 2024, which is incorporated herein by reference in its entirety.

### TECHNICAL FIELD

The present disclosure relates to a semiconductor device structure and a method of manufacturing the same, and more particularly, to a semiconductor device structure including an interposer.

### DISCUSSION OF THE BACKGROUND

With the rapid growth of the electronics industry, integrated circuits (ICs) capable of delivering very high performance in extremely small packages have been developed. Technological advances in IC materials and design have produced generations of ICs, with each generation having smaller and more complex circuits than the previous.

Memories, such as a cache memory, a dynamic random-access memory (DRAM), and the like, are utilized to store data from logic circuits. Recent semiconductor device structures including memories and logic circuits now face significant challenges to continued miniaturization. Therefore, a new semiconductor device structure is required.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a semiconductor device structure. The semiconductor device structure includes an interposer and a first electronic component. The interposer includes a first semiconductor die and a second semiconductor die. The first semiconductor die includes a first cache memory and a first memory control circuit. The second semiconductor die includes a second cache memory and a second memory control circuit. The first electronic component is disposed on the interposer and is in communication with the first semiconductor die and the second semiconductor die. The first semiconductor die comprises at least one first air gap structure.

Another aspect of the present disclosure provides another semiconductor device structure. The semiconductor device structure includes an interposer and a first electronic component. The interposer includes a first semiconductor die and a second semiconductor die. The first semiconductor die includes a first cache memory and a first memory control circuit. The second semiconductor die includes a second cache memory and a second memory control circuit. The first electronic component is disposed on the interposer and is in communication with the first semiconductor die and the second semiconductor die. The first semiconductor die comprises at least one first through via extending from a first surface of the first semiconductor die. The first through via has non-uniform critical dimensions.

Another aspect of the present disclosure provides a method of manufacturing a semiconductor device structure. The method includes: providing a first semiconductor die and a second semiconductor die, wherein the first semiconductor die comprises a first cache memory and at least one first air gap structure formed under the first cache memory, and the second semiconductor die comprises a second cache memory; forming a first redistribution structure on the first semiconductor die and the second semiconductor die; and attaching a first electronic component to the first redistribution structure, wherein the first electronic component is in communication with the first cache memory, the second cache memory, or both via the first redistribution structure.

Another aspect of the present disclosure provides a method of manufacturing a semiconductor device structure. The method includes: providing a first semiconductor die and a second semiconductor die, wherein the first semiconductor die comprises a first cache memory and at least one first through via, and the second semiconductor die comprises a second cache memory, wherein the first through via has non-uniform critical dimensions; forming a first redistribution structure on the first semiconductor die and the second semiconductor die; and attaching a first electronic component to the first redistribution structure, wherein the first electronic component is in communication with the first cache memory, the second cache memory, or both via the Embodiments of the present disclosure provide a semiconductor device structure. The semiconductor device structure includes an interposer, which includes a cache memory formed within a semiconductor die. Logic circuits are disposed in an electronic component separate from the semiconductor die, which reduces the size of the electronic component. In a comparative example, the logic circuits and cache memory are integrated in a die, which increases a size of the die and adversely affects miniaturization of a semiconductor device structure. In some embodiments, the interposer includes two or more semiconductor dies. Each semiconductor die includes a cache memory and a memory control circuit. The logic circuit may be in communication with any one of semiconductor dies, or in communication with or two or more semiconductor dies. Such design can improve a yield of manufacturing the semiconductor device structure.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1A is a top view of a semiconductor device structure, in accordance with some embodiments of the present disclosure.

FIG. 1B is a cross-sectional view along line A-A′ of the semiconductor device structure as shown in FIG. 1A, in accordance with some embodiments of the present disclosure.

FIG. 1C is a cross-sectional view along line A-A′ of the semiconductor device structure as shown in FIG. 1A, in accordance with some embodiments of the present disclosure.

FIG. 2A is a top view of a semiconductor device structure, in accordance with some embodiments of the present disclosure.

FIG. 2B is a cross-sectional view along line B-B′ of the semiconductor device structure as shown in FIG. 2A, in accordance with some embodiments of the present disclosure.

FIG. 2C is a cross-sectional view along line B-B′ of the semiconductor device structure as shown in FIG. 2A, in accordance with some embodiments of the present disclosure.

FIG. 3 is a flowchart illustrating a method of manufacturing a semiconductor device structure, in accordance with some embodiments of the present disclosure.

FIG. 4A illustrates one or more stages of an exemplary method of manufacturing a semiconductor device structure according to some embodiments of the present disclosure.

FIG. 4B illustrates one or more stages of an exemplary method of manufacturing a semiconductor device structure according to some embodiments of the present disclosure.

FIG. 4C illustrates one or more stages of an exemplary method of manufacturing a semiconductor device structure according to some embodiments of the present disclosure.

FIG. 4D illustrates one or more stages of an exemplary method of manufacturing a semiconductor device structure according to some embodiments of the present disclosure.

FIG. 4E illustrates one or more stages of an exemplary method of manufacturing a semiconductor device structure according to some embodiments of the present disclosure.

FIG. 4F illustrates one or more stages of an exemplary method of manufacturing a semiconductor device structure according to some embodiments of the present disclosure.

FIG. 5 is a flowchart illustrating a method of manufacturing a semiconductor device structure, in accordance with other embodiments of the present disclosure.

FIG. 6A illustrates one or more stages of an exemplary method of manufacturing a semiconductor device structure according to some embodiments of the present disclosure.

FIG. 6B illustrates one or more stages of an exemplary method of manufacturing a semiconductor device structure according to some embodiments of the present disclosure.

FIG. 6C illustrates one or more stages of an exemplary method of manufacturing a semiconductor device structure according to some embodiments of the present disclosure.

FIG. 6D illustrates one or more stages of an exemplary method of manufacturing a semiconductor device structure according to some embodiments of the present disclosure.

FIG. 6E illustrates one or more stages of an exemplary method of manufacturing a semiconductor device structure according to some embodiments of the present disclosure.

FIG. 6F illustrates one or more stages of an exemplary method of manufacturing a semiconductor device structure according to some embodiments of the present disclosure.

### DETAILED DESCRIPTION

Embodiments, or examples, of the disclosure illustrated in the drawings are now described using specific language. It should be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It should be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It should be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

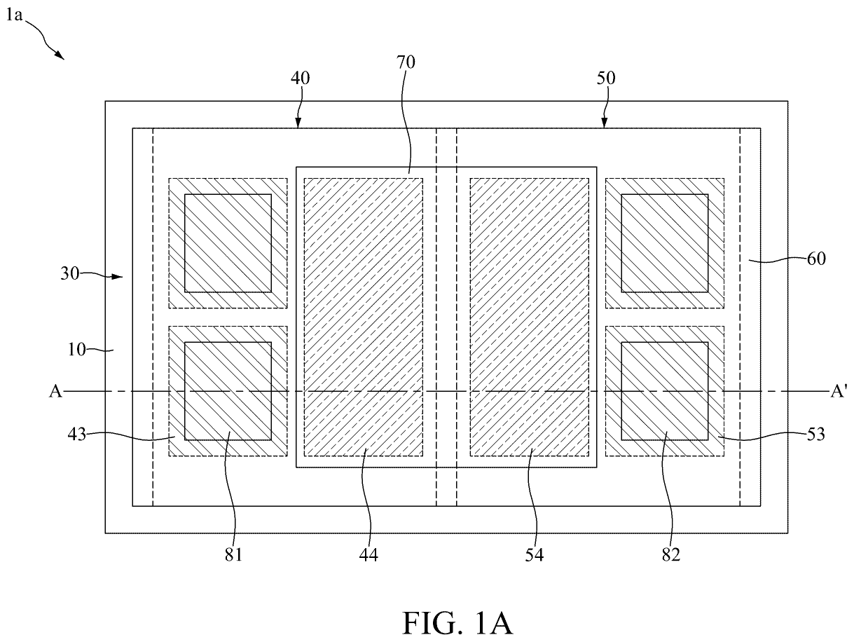

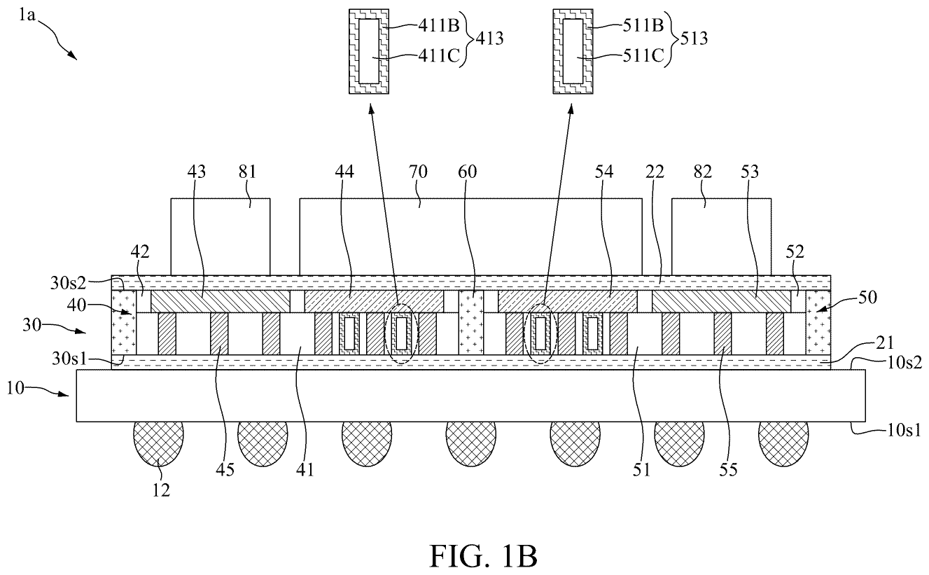

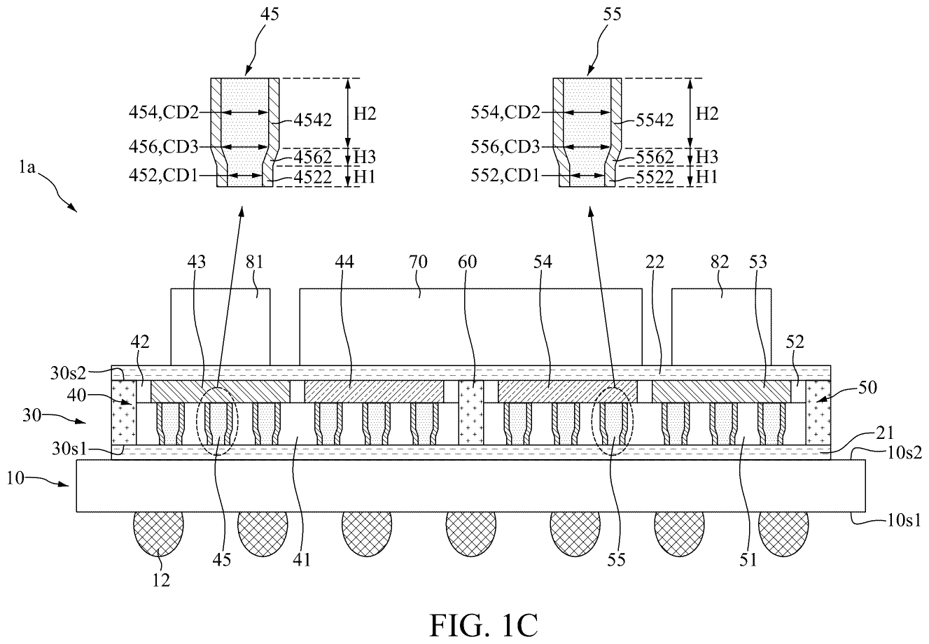

FIG. 1A is a top view of a semiconductor device structure 1a, FIG. 1B is a cross-sectional view along line A-A′ of the semiconductor device structure 1a as shown in FIG. 1A, and FIG. 1C is a cross-sectional view along line A-A′ of the semiconductor device structure as shown in FIG. 1A, in accordance with some embodiments of the present disclosure.

As shown in FIGS. 1A to 1C, in some embodiments, the semiconductor device structure 1a may include a carrier 10, redistribution structures 21 and 22, an interposer 30, and electronic components 70, 81 and 82.

The carrier 10 may be formed of, for example, a printed circuit board (PCB), such as a paper-based copper foil laminate, a composite copper foil laminate, or a polymer-impregnated glass-fiber-based copper foil laminate. The carrier 10 may include a redistribution structure, which includes one or more dielectric layers, one or more conductive traces, and one or more conductive vias (not shown). The carrier 10 may include a surface 10s1 (or a bottom surface) and a surface 10s2 (or a top surface) opposite to the surface 10s1.

The semiconductor device structure 1a may further include connection elements 12. Each of the connection elements 12 may be disposed on the surface 10s1 of the carrier 10. Each of the connection elements 12 may be configured to electrically connect the semiconductor device structure 1a to external devices (not shown). The connection element 12 may be, or may include, electrical contacts, such as solder balls, conductive bumps, or the like. The connection element 12 may include alloys of gold and tin solder or alloys of silver and tin solder, or other suitable materials.

The redistribution structure 21 may be disposed on the surface 10s2 of the carrier 10. The redistribution structure 21 may be in contact with the carrier 10. The redistribution structure 21 may include one or more dielectric layers, one or more conductive traces, and one or more conductive vias (not shown). The dielectric layer may include an insulating material, a passivation material, a dielectric material or a solder resist material, such as, for example, a benzocyclobutene (BCB) based polymer or a polyimide (PI). The dielectric layer may be made of a photoimageable material. The conductive trace may be disposed on or disposed over a surface (e.g., a top surface or a bottom surface) of the dielectric layer. The conductive via may be disposed on or disposed over a surface (e.g., a top surface or a bottom surface) of the conductive trace. A material of the conductive trace and a material of the conductive via may include, for example, copper, aluminum, titanium, another conductive metal, or an alloy thereof. In some embodiments, a dimension (e.g., width, surface area, and/or aperture) of the conductive trace (or the conductive via) within the redistribution structure 21 may be less than such dimension of the conductive trace (or the conductive via) within the carrier 10.

In some embodiments, the interposer 30 may be disposed on the surface 10s2 of the carrier 10. In some embodiments, the interposer 30 may be disposed on the redistribution structure 21. In some embodiments, the interposer 30 may be electrically connected to the carrier 10 through the redistribution structure 21. In some embodiments, the interposer 30 may be spaced apart from the carrier 10 by the redistribution structure 21. In some embodiments, the interposer 30 may be configured to be in communication with the electronic component 70. In some embodiments, the interposer 30 may include two or more semiconductor dies. For example, the interposer 30 may include a first semiconductor die 40 and a second semiconductor die 50. The interposer 30 may have a surface 30s1 and a surface 30s2 opposite to the surface 30s1. The surface 30s1 of the interposer 30 may abut and/or face the redistribution structure 21. The redistribution structure 21 may be disposed on the surface 30s1 of the interposer 30. The surface 30s2 of the interposer 30 may abut and/or face the redistribution structure 22. The surface 30s2 of the interposer 30 may abut and/or face the electronic component 70.

In some embodiments, the first semiconductor die 40 may be disposed on the redistribution structure 21. In some embodiments, the first semiconductor die 40 may be electrically connected to the carrier 10 through the redistribution structure 21. In some embodiments, the first semiconductor die 40 may be spaced apart from the carrier 10 by the redistribution structure 21. In some embodiments, the first semiconductor die 40 may be configured to be in communication with the electronic component 70. The first semiconductor die 40 may include a first semiconductor substrate 41, a first circuit region 42, and first through vias 45.

The first semiconductor substrate 41 may include a bulk semiconductor, a semiconductor-on-insulator (SOI) substrate, or the like. The first semiconductor substrate 41 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy.

The first circuit region 42 may be disposed on the first semiconductor substrate 41. The first circuit region 42 may include one or more dielectric layers and one or more integrated circuits (ICs) at least partially embedded in one or more dielectric layers. The first circuit region 42 may include one or more interconnections connected to the ICs. The first circuit region 42 may include a first memory control circuit 43 and a first cache memory 44.

The first memory control circuit 43 may be disposed on the first semiconductor substrate 41. The first memory control circuit 43 may be disposed within the first circuit region 42. The first memory control circuit 43 may receive signals from the first cache memory 44, the electronic component 70, the electronic component 81, and/or other components. The first memory control circuit 43 may be configured to manage and process data transmitted between the electronic component 70 and other circuits (e.g., the first cache memory 44, the electronic component 81, and/or other ICs) operating according to a different communication standard. The first memory control circuit 43 may include various memory controllers, for example, devices which may control IDE (integrated device electronics), a SATA (serial advanced technology attachment), an SCSI (small computer system interface), a RAID (redundant array of independent disks), an SSD (solid state disk), an eSATA (external SATA), a PCMCIA (Personal Computer Memory Card International Association) card (also known as a PC card), a USB (universal serial bus), a secure digital (SD) card, a mini secure digital (mini SD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The first cache memory 44 may be disposed on the first semiconductor substrate 41. The first cache memory 44 may be disposed within the first circuit region 42. In some embodiments, the first memory control circuit 43 may be in communication with the first cache memory 44. In some embodiments, the first cache memory 44 may be configured to temporarily store data (e.g., a signal from the electronic component 70). In some embodiments, the first cache memory 44 may be configured to compensate for a difference between data processing speeds of the electronic component 70 operating at a high speed and an external device (not shown) operating at a low speed. In some embodiments, the first cache memory 44 may be configured to store data for performing an operation, data corresponding to a result of an operation, or an address of data for which an operation is performed. In some embodiments, the first cache memory 44 may include a static random-access memory (SRAM) or other suitable memory.

In some embodiments, the first through via 45 may penetrate the first semiconductor substrate 41. In some embodiments, the first through via 45 may be disposed between the first circuit region 42 and the redistribution structure 21. In some embodiments, the first through via 45 may be disposed between the first memory control circuit 43 and the redistribution structure 21. In some embodiments, the first through via 45 may be disposed between the first cache memory 44 and the redistribution structure 21. In some embodiments, the first through via 45 may be electrically connected to the first memory control circuit 43. In some embodiments, the first through via 45 may be electrically connected to the first cache memory 44. In some embodiments, the first through via 45 may include a through-silicon via (TSV). In some embodiments, the first through via 45 may include copper, aluminum, titanium, another conductive metal, or an alloy thereof.

As shown in FIG. 1B, in some embodiments, an air gap structure 413 may be disposed between two adjacent through vias 45. In particular, in some embodiments, the air gap structure 413 may be disposed between two adjacent through vias 45 under the cache memory 44. In some embodiments, the air gap structure 413 includes an air gap 411C and a liner 411B, wherein the air gap 411C is enclosed by the liner 411B.

As shown in FIG. 1C, in some embodiments, the first through via 45 includes a first block 452 having a uniform first critical dimension CD1, a second block 454 having a uniform second critical dimension CD2 different from the first critical dimension CD1, and a third block 456 having a varying third critical dimension CD3, wherein the third block 456 connects the second block 454 to the first block 452. In particular, the first critical dimension CD1 is less than the second critical dimension CD2, and the third critical dimension CD3 gradually increases at positions of increasing distance from the first block 452, and gradually decreases at positions of increasing distance from the second block 454. As a result, the first and second blocks 452 and 454 have vertical peripheral surfaces 4522 and 4542, and the third block 456 has an inclined peripheral surface 4562.

In some embodiments, the first block 452 of the first through via 45 has a first height H1. In addition, the second block 454 of the first through via 45 has a second height H2 greater than the first height H1, and the third block 456 of the first through via 45 has a third height H3 less than the first height H1. In some embodiments, the first height H1 is greater than 1 μm.

The non-uniform critical dimension of the first through via 45 may increase utilization of the first semiconductor substrate 41. In some embodiments, the first through via 45 can be provided using a via-last process.

In some embodiments, the second semiconductor die 50 may be disposed on the redistribution structure 21. In some embodiments, the second semiconductor die 50 may be electrically connected to the carrier 10 through the redistribution structure 21. In some embodiments, the second semiconductor die 50 may be spaced apart from the carrier 10 by the redistribution structure 21. In some embodiments, the second semiconductor die 50 may be configured to be in communication with the electronic component 70. The first semiconductor die 40 and the second semiconductor die 50 may be located at a same level. The first semiconductor die 40 may be spaced apart from the second semiconductor die 50. The second semiconductor die 50 may include a second semiconductor substrate 51, a second circuit region 52, and second through vias 55. A structure and materials of the second semiconductor die 50 may be similar to or same as those of the first semiconductor die 40.

The second semiconductor substrate 51 may include a bulk semiconductor, a semiconductor-on-insulator (SOI) substrate, or the like. The second semiconductor substrate 51 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy.

The second circuit region 52 may be disposed on the second semiconductor substrate 51. The second circuit region 52 may include one or more dielectric layers and integrated circuits (ICs) at least partially embedded in one or more dielectric layers. The second circuit region 52 may include a second memory control circuit 53 and a second cache memory 54.

The second memory control circuit 53 may be disposed on the second semiconductor substrate 51. The second memory control circuit 53 may be disposed within the second circuit region 52. The second memory control circuit 53 may receive signals from the second cache memory 54, the electronic component 70, the electronic component 82, and/or other components. The second memory control circuit 53 may be configured to manage and process data transmitted between the electronic component 70 and other circuits (e.g., the cache memory 54, the electronic component 82, and/or other ICs) operating according to a different communication standard. The second memory control circuit 53 may include various memory controllers, for example, devices which may control IDE (integrated device electronics), a SATA (serial advanced technology attachment), a SCSI (small computer system interface), a RAID (redundant array of independent disks), an SSD (solid state disk), an eSATA (external SATA), a PCMCIA (Personal Computer Memory Card International Association) card (also known as a PC card), a USB (universal serial bus), a secure digital (SD) card, a mini secure digital (mini SD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The second cache memory 54 may be disposed on the second semiconductor substrate 51. The second cache memory 54 may be disposed within the second circuit region 52. In some embodiments, the second memory control circuit 53 may be in communication with the second cache memory 54. In some embodiments, the second cache memory 54 may be configured to temporarily store data (e.g., a signal from the electronic component 70). In some embodiments, the second cache memory 54 may be configured to compensate for a difference between data processing speeds of the electronic component 70 operating at a high speed and an external device (not shown) operating at a low speed. In some embodiments, the second cache memory 54 may be configured to store data for performing an operation, data corresponding to a result of an operation, or an address of data for which an operation is performed. In some embodiments, the second cache memory 54 may include an SRAM or another suitable memory.

In some embodiments, the second through via 55 may penetrate the second semiconductor substrate 51. In some embodiments, the second through via 55 may be disposed between the second circuit region 52 and the redistribution structure 21. In some embodiments, the second through via 55 may be disposed between the second memory control circuit 53 and the redistribution structure 21. In some embodiments, the second through via 55 may be disposed between the second cache memory 54 and the redistribution structure 21. In some embodiments, the second through via 55 may be electrically connected to the second memory control circuit 53. In some embodiments, the second through via 55 may be electrically connected to the second cache memory 54. In some embodiments, the second through via 55 may include a through-silicon via (TSV). In some embodiments, the second through via 55 may include copper, aluminum, titanium, another conductive metal, or an alloy thereof.

As shown in FIG. 1B, in some embodiments, an air gap structure 513 may be disposed between two adjacent through vias 55. In some embodiments, the air gap structure 513 may be disposed between two adjacent through vias 55 under the cache memory 54. In some embodiments, the air gap structure 513 includes an air gap 511C and a liner 511B, wherein the air gap 511C is enclosed by the liner 511B.

As shown in FIG. 1C, in some embodiments, the second through via 55 includes a first block 552 having a uniform first critical dimension CD1, a second block 554 having a uniform second critical dimension CD2 different from the first critical dimension CD1, and a third block 556 having a varying third critical dimension CD3, wherein the third block 556 connects the second block 554 to the first block 552. In particular, the first critical dimension CD1 is less than the second critical dimension CD2, and the third critical dimension CD3 gradually increases at positions of increasing distance from the first block 552, and gradually decreases at positions of increasing distance from the second block 554. As a result, the first and second blocks 552 and 554 have vertical peripheral surfaces 5522 and 5542, and the third block 556 has an inclined peripheral surface 5562.

In some embodiments, the first block 552 of the second through via 55 has a first height H1. In addition, the second block 554 of the second through via 55 has a second height H2 greater than the first height H1, and the third block 556 of the second through via 55 has a third height H3 less than the first height H1. In some embodiments, the first height H1 is greater than 1 μm.

The variable critical dimensions of the second through via 55 may increase utilization of the second semiconductor substrate 51. In some embodiments, the second through via 55 can be provided using a via-last process.

In some embodiments, the circuits (e.g., the first memory control circuit 43 and the first cache memory 44) of the first semiconductor die 40 and the circuits (e.g., the second memory control circuit 53 and second cache memory 54) of the second semiconductor die 50 may have a mirror symmetry. In some embodiments, a distance from the first cache memory 44 of the first semiconductor die 40 to the second cache memory 54 of the second semiconductor die 50 may be less than a distance from the first memory control circuit 43 to the second cache memory 54 of the second semiconductor die 50. In some embodiments, the first cache memory 44 may be disposed between the second cache memory 54 and the second memory control circuit 53.

In some embodiments, the interposer 30 may further include an encapsulant 60. In some embodiments, the encapsulant 60 may encapsulate the first semiconductor die 40. In some embodiments, the encapsulant 60 may encapsulate the second semiconductor die 50. In some embodiments, the encapsulant 60 may be disposed between the redistribution structures 21 and 22. In some embodiments, the encapsulant 60 may be in contact with the redistribution structure 21. In some embodiments, the encapsulant 60 may be in contact with the redistribution structure 22. In some embodiments, a bottom surface (not indicated in FIG. 1C) of the encapsulant 60 may be substantially coplanar with a bottom surface (not indicated in FIG. 1C) of the first semiconductor die 40. In some embodiments, the bottom surface of the encapsulant 60 may be substantially coplanar with a bottom surface (not indicated in FIG. 1C) of the second semiconductor die 50. In some embodiments, the encapsulant 60 includes, for example, organic materials (e.g., a molding compound, bismaleimide triazine (BT), polyimide (PI), polybenzoxazole (PBO), a solder resist, ABF, polypropylene (PP), or an epoxy-based material), inorganic materials (e.g., silicon, glass, ceramic or quartz), liquid and/or dry-film materials, or a combination thereof. Suitable fillers may also be included, such as powdered SiO₂.

In some embodiments, the redistribution structure 22 may be disposed on the surface 30s2 of the interposer 30. The redistribution structure 22 may include one or more dielectric layers, one or more conductive traces, and one or more conductive vias (not shown). The dielectric layer may include an insulating material, a passivation material, a dielectric material or a solder resist material, such as, for example, a benzocyclobutene (BCB) based polymer or polyimide (PI). The dielectric layer may be made of a photoimageable material. The conductive trace may be disposed on or over a surface (e.g., a top surface or a bottom surface) of the dielectric layer. The conductive via may be disposed on or over a surface (e.g., a top surface or a bottom surface) of the conductive trace. Materials of the conductive trace and the conductive via may include, for example, copper, aluminum, titanium, another conductive metal, or an alloy thereof. In some embodiments, a dimension (e.g., width, surface area, and/or aperture) of the conductive trace (or the conductive via) within the redistribution structure 22 may be less than such dimension of the conductive trace (or the conductive via) within the carrier 10. In some embodiments, a lateral surface of the redistribution structure 22 may be aligned with a lateral surface of the redistribution structure 21. In some embodiments, the lateral surface of the redistribution structure 22 may be aligned with a lateral surface of the interposer 30. In some embodiments, the lateral surface of the redistribution structure 22 may be aligned with a lateral surface of the encapsulant 60.

In some embodiments, the electronic component 70 may be disposed on the surface 30s2 of the interposer 30. In some embodiments, the electronic component 70 may be disposed on the redistribution structure 22. In some embodiments, the electronic component 70 may be spaced apart from the interposer 30 by the redistribution structure 22. In some embodiments, the electronic component 70 may vertically overlap the first cache memory 44. In some embodiments, the electronic component 70 may vertically overlap the second cache memory 54. In some embodiments, the electronic component 70 may be free from vertically overlapping the first memory control circuit 43. In some embodiments, the electronic component 70 may be free from vertically overlapping the second memory control circuit 53. In some embodiments, the electronic component 70 may be electrically connected to or in communication with the first memory control circuit 43 via the redistribution structure 22. In some embodiments, the electronic component 70 may be electrically connected to or in communication with the first cache memory 44 via the redistribution structure 22. In some embodiments, the electronic component 70 may be electrically connected to or in communication with the second memory control circuit 53 via the redistribution structure 22. In some embodiments, the electronic component 70 may be electrically connected to or in communication with the second cache memory 54 via the redistribution structure 22. In some embodiments, the electronic component 70 may be electrically connected to or in communication with the cache memories 44 and 54 via the redistribution structure 22. In some embodiments, the electronic component 70 may include logic circuits and/or other suitable circuits. In some embodiments, the electronic component 70 may include a central processing unit (CPU), a microprocessor unit (MPU), a graphics processing unit (GPU), a microcontroller unit (MCU), a field-programmable gate array (FPGA), an application processor (AP) or another type of IC. In some embodiments, the electronic component 70 does not include a cache memory.

In some embodiments, the electronic component 81 may be disposed on the surface 30s2 of the interposer 30. In some embodiments, the electronic component 81 may be disposed on the redistribution structure 22. In some embodiments, the electronic component 81 may be spaced apart from the interposer 30 by the redistribution structure 22. In some embodiments, the electronic component 81 may vertically overlap the first memory control circuit 43. In some embodiments, the electronic component 81 may be free from vertically overlapping the first cache memory 44. In some embodiments, the electronic component 81 may be electrically connected to or in communication with the electronic component 70 via the redistribution structure 22. In some embodiments, the electronic component 81 may be electrically connected to or in communication with the first memory control circuit 43 via the redistribution structure 22. In some embodiments, the electronic component 81 may include a dynamic random-access memory (DRAM). For example, the electronic component 81 may include at least a transistor(s), at least a capacitor(s), and/or other suitable elements. In some embodiments, the electronic component 81 may include a high bandwidth memory (HBM).

In some embodiments, the electronic component 82 may be disposed on the surface 30s2 of the interposer 30. In some embodiments, the electronic component 82 may be disposed on the redistribution structure 22. In some embodiments, the electronic component 82 may be spaced apart from the interposer 30 by the redistribution structure 22. In some embodiments, the electronic component 82 may vertically overlap the second memory control circuit 53. In some embodiments, the electronic component 82 may be free from vertically overlapping the second cache memory 54. In some embodiments, the electronic component 82 may be electrically connected to or in communication with the electronic component 70 via the redistribution structure 22. In some embodiments, the electronic component 82 may be electrically connected to or in communication with the second memory control circuit 53 via the redistribution structure 22. In some embodiments, the electronic component 82 may include a DRAM. For example, the electronic component 82 may include at least a transistor(s), at least a capacitor(s), and/or other suitable elements. In some embodiments, the electronic component 82 may include an HBM.

In a comparative example, the logic circuits and cache memory(s) are integrated as a die, which increases a size of the die and adversely affects miniaturization of a semiconductor device structure. In the embodiments of the present disclosure, the semiconductor device structure includes an electronic component and a semiconductor die. The logic circuit(s) are disposed within the electronic component (e.g., the electronic component 70), and the cache memory is disposed within the semiconductor die (e.g., the first semiconductor die 40 and/or the second semiconductor die 50). Therefore, a size of the electronic component is reduced, thereby facilitating the miniaturization of the semiconductor device structure. Further, the cache memories may include at least two portions disposed within two semiconductor dies. As a result, the logic circuit(s) may be in communication with one or more semiconductor dies according to requirements. Further, such design may improve a manufacturing yield of the semiconductor device structure.

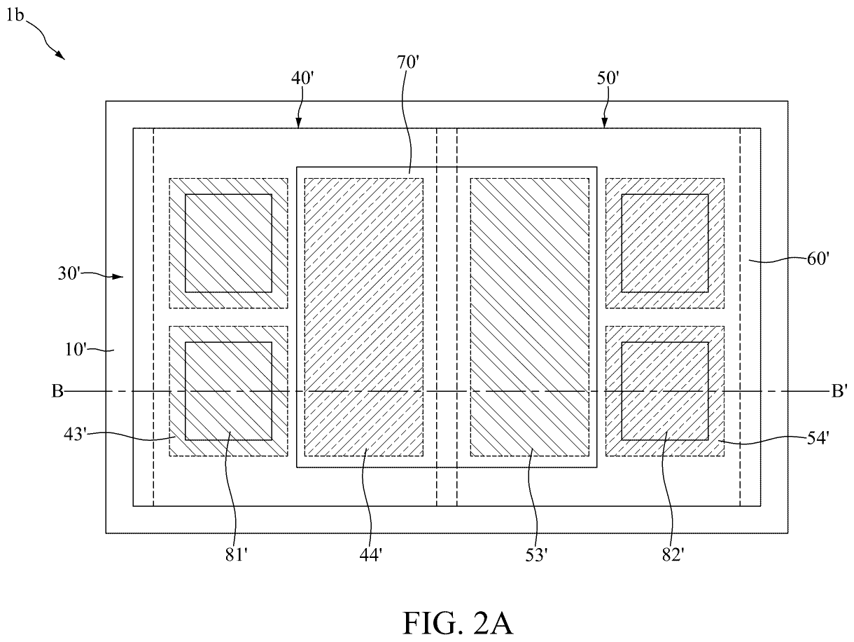

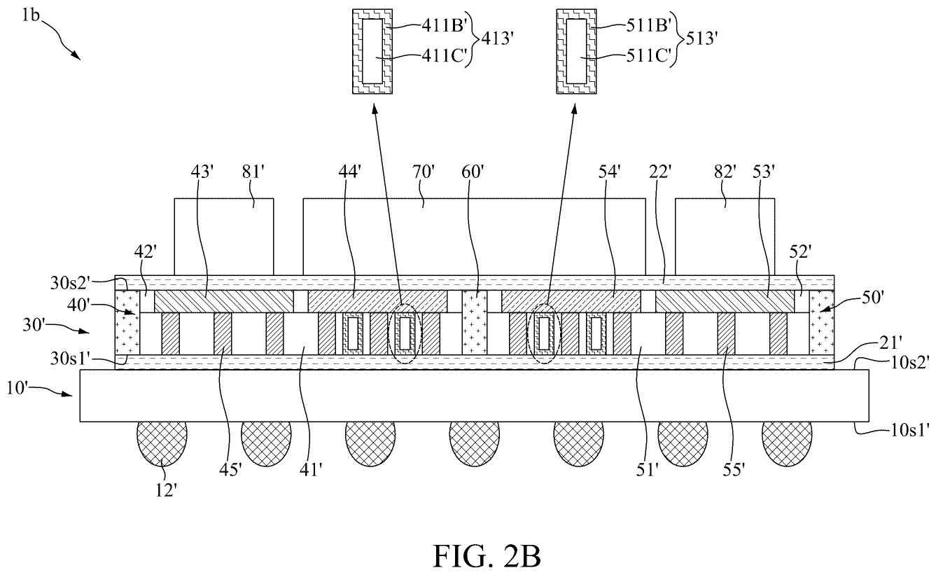

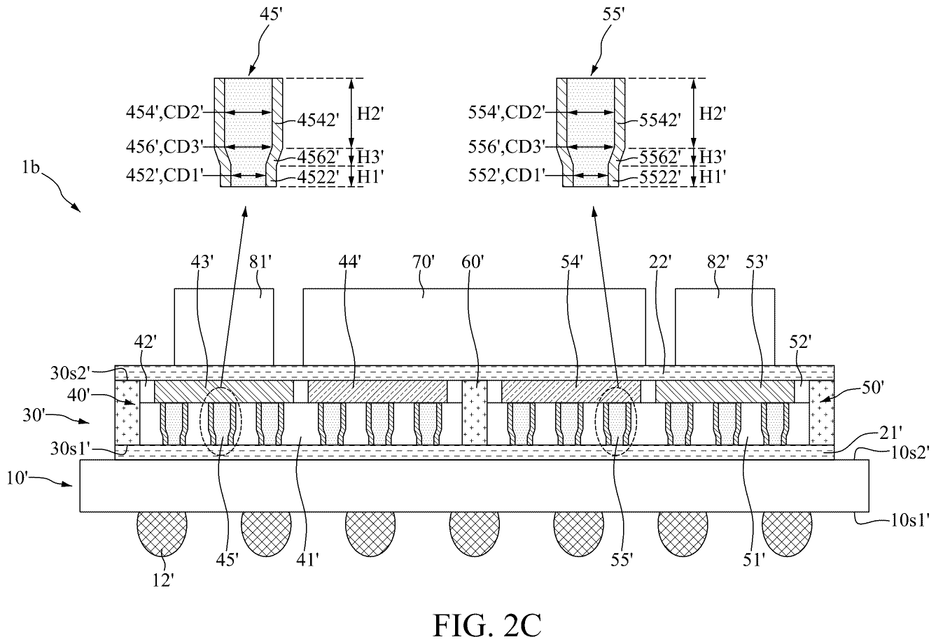

FIG. 2A is a top view of a semiconductor device structure 1b, FIG. 2B is a cross-sectional view along line B-B′ of the semiconductor device structure 1b as shown in FIG. 2A, and FIG. 2C is a cross-sectional view along line B-B′ of the semiconductor device structure 1b as shown in FIG. 2A, in accordance with some embodiments of the present disclosure.

As shown in FIGS. 2A to 2C, in some embodiments, the semiconductor device structure 1b may include a carrier 10′, redistribution structures 21′ and 22′, an interposer 30′, and electronic components 70′, 81′ and 82′.

The carrier 10′ may be formed of, for example, a printed circuit board (PCB), such as a paper-based copper foil laminate, a composite copper foil laminate, or a polymer-impregnated glass-fiber-based copper foil laminate. The carrier 10′ may include a redistribution structure, which includes one or more dielectric layers, one or more conductive traces, and one or more conductive vias (not shown). The carrier 10′ may include a surface 10s1′ (or a bottom surface) and a surface 10s2′ (or a top surface) opposite to the surface 10s1′.

The semiconductor device structure 1b may further include connection elements 12′. Each of the connection elements 12′ may be disposed on the surface 10s1′ of the carrier 10′. Each of the connection elements 12′ may be configured to electrically connect the semiconductor device structure 1b to external devices (not shown). The connection element 12′ may be or may include electrical contacts, such as solder balls, conductive bumps, or the like. The connection element 12′ may include alloys of gold and tin solder, alloys of silver and tin solder, or other suitable materials.

The redistribution structure 21′ may be disposed on the surface 10s2′ of the carrier 10′. The redistribution structure 21′ may be in contact with the carrier 10′. The redistribution structure 21′ may include one or more dielectric layers, one or more conductive traces, and one or more conductive vias (not shown). The dielectric layer may include an insulating material, a passivation material, a dielectric material or a solder resist material, such as, for example, a benzocyclobutene (BCB) based polymer or polyimide (PI). The dielectric layer may be made of a photoimageable material. The conductive trace may be disposed on or over a surface (e.g., a top surface or a bottom surface) of the dielectric layer. The conductive via may be disposed on or over a surface (e.g., a top surface or a bottom surface) of the conductive trace. Materials of the conductive trace and the conductive via may include, for example, copper, aluminum, titanium, another conductive metal, or an alloy thereof. In some embodiments, a dimension (e.g., width, surface area, and/or aperture) of the conductive trace (or the conductive via) within the redistribution structure 21′ may be less than such dimension of the conductive trace (or the conductive via) within the carrier 10′.

In some embodiments, the interposer 30′ may be disposed on the surface 10s2′ of the carrier 10′. In some embodiments, the interposer 30′ may be disposed on the redistribution structure 21′. In some embodiments, the interposer 30′ may be electrically connected to the carrier 10′ through the redistribution structure 21′. In some embodiments, the interposer 30′ may be spaced apart from the carrier 10′ by the redistribution structure 21′. In some embodiments, the interposer 30′ may be configured to be in communication with the electronic component 70′. In some embodiments, the interposer 30′ may include two or more semiconductor dies. For example, the interposer 30′ may include a semiconductor die 40′ and a semiconductor die 50′. The interposer 30′ may have a surface 30s1′ and a surface 30s2′ opposite to the surface 30s1′. The surface 30s1′ of the interposer 30′ may abut and/or face the redistribution structure 21′. The redistribution structure 21′ may be disposed on the surface 30s1′ of the interposer 30′. The surface 30s2′ of the interposer 30′ may abut and/or face the redistribution structure 22′. The surface 30s2′ of the interposer 30′ may abut and/or face the electronic component 70′.

In some embodiments, the first semiconductor die 40′ may be disposed on the redistribution structure 21′. In some embodiments, the first semiconductor die 40′ may be electrically connected to the carrier 10′ through the redistribution structure 21′. In some embodiments, the first semiconductor die 40′ may be spaced apart from the carrier 10′ by the redistribution structure 21′. In some embodiments, the first semiconductor die 40′ may be configured to be in communication with the electronic component 70′. The first semiconductor die 40′ may include a first semiconductor substrate 41′, a first circuit region 42′, and first through vias 45′.

The first semiconductor substrate 41′ may include a bulk semiconductor, a semiconductor-on-insulator (SOI) substrate, or the like. The first semiconductor substrate 41′ can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy.

The first circuit region 42′ may be disposed on the first semiconductor substrate 41′. The first circuit region 42′ may include one or more dielectric layers and integrated circuits (ICs) at least partially embedded in one or more dielectric layers. The first circuit region 42′ may include one or more interconnections connected to the ICs. The first circuit region 42′ may include a first memory control circuit 43′ and a first cache memory 44′.

The first memory control circuit 43′ may be disposed on the first semiconductor substrate 41′. The first memory control circuit 43′ may be disposed within the first circuit region 42′. The first memory control circuit 43′ may receive signals from the first cache memory 44′, the electronic component 70′, the electronic component 81′, and/or other components. The first memory control circuit 43′ may be configured to manage and process data transmitted between the electronic component 70′ and other circuits (e.g., the cache memory 44′, the electronic component 81′, and/or other ICs) operating according to a different communication standard. The first memory control circuit 43′ may include various memory controllers, for example, devices which may control IDE (integrated device electronics), a SATA (serial advanced technology attachment), an SCSI (small computer system interface), a RAID (redundant array of independent disks), an SSD (solid state disk), an eSATA (external SATA), a PCMCIA (Personal Computer Memory Card International Association) card (also known as a PC card), a USB (universal serial bus), a secure digital (SD) card, a mini secure digital (mini SD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The first cache memory 44′ may be disposed on the first semiconductor substrate 41′. The first cache memory 44′ may be disposed within the first circuit region 42′. In some embodiments, the first memory control circuit 43′ may be in communication with the first cache memory 44′. In some embodiments, the first cache memory 44′ may be configured to temporarily store data (e.g., a signal from the electronic component 70′). In some embodiments, the first cache memory 44′ may be configured to compensate for a difference between data processing speeds of the electronic component 70′ operating at a high speed and an external device (not shown) operating at a low speed. In some embodiments, the first cache memory 44′ may be configured to store data for performing an operation, data corresponding to a result of an operation, or an address of data for which an operation is performed. In some embodiments, the first cache memory 44′ may include a static random-access memory (SRAM) or other suitable memories.

In some embodiments, the first through via 45′ may penetrate the first semiconductor substrate 41′. In some embodiments, the first through via 45′ may be disposed between the first circuit region 42′ and the redistribution structure 21′. In some embodiments, the first through via 45′ may be disposed between the first memory control circuit 43′ and the redistribution structure 21′. In some embodiments, the first through via 45′ may be disposed between the first cache memory 44′ and the redistribution structure 21′. In some embodiments, the first through via 45′ may be electrically connected to the first memory control circuit 43′. In some embodiments, the first through via 45′ may be electrically connected to the first cache memory 44′. In some embodiments, the first through via 45′ may include a through-silicon via (TSV). In some embodiments, the first through via 45′ may include copper, aluminum, titanium, another conductive metal, or an alloy thereof.

As shown in FIG. 2B, in some embodiments, an air gap structure 413′ may be disposed between two adjacent through vias 45′. In some embodiments, the air gap structure 413′ may be disposed between two adjacent through vias 45′ under the cache memory 44′. In some embodiments, the air gap structure 413′ includes an air gap 411C′ and a liner 411B′, wherein the air gap 411C′ is enclosed by the liner 411B′.

As shown in FIG. 2C, in some embodiments, the first through via 45′ includes a first block 452′ having a uniform first critical dimension CD1′, a second block 454′ having a uniform second critical dimension CD2′ different from the first critical dimension CD1′, and a third block 456′ having a varying third critical dimension CD3′, wherein the third block 456′ connects the second block 454′ to the first block 452′. In particular, the first critical dimension CD1′ is less than the second critical dimension CD2′, and the third critical dimension CD3′ gradually increases at positions of increasing distance from the first block 452′, and gradually decreases at positions of increasing distance from the second block 454′. As a result, the first and second blocks 452′ and 454′ have vertical peripheral surfaces 4522′ and 4542′, and the third block 456′ has an inclined peripheral surface 4562′.

In some embodiments, the first block 452′ of the first through via 45′ has a first height H1′. In addition, the second block 454′ of the first through via 45′ has a second height H2′ greater than the first height H1′, and the third block 456′ of the first through via 45′ has a third height H3′ less than the first height H1′. In some embodiments, the first height H1′ is greater than 1 μm.

The non-uniform critical dimension of the first through via 45′ may increase utilization of the first semiconductor substrate 41′. In some embodiments, the first through via 45′ can be provided using a via-last process.

In some embodiments, the second semiconductor die 50′ may be disposed on the redistribution structure 21′. In some embodiments, the second semiconductor die 50′ may be electrically connected to the carrier 10′ through the redistribution structure 21′. In some embodiments, the second semiconductor die 50′ may be spaced apart from the carrier 10′ by the redistribution structure 21′. In some embodiments, the second semiconductor die 50′ may be configured to be in communication with the electronic component 70′. The first semiconductor die 40′ and the second semiconductor die 50′ may be located at a same level. The first semiconductor die 40′ may be spaced apart from the second semiconductor die 50′. The second semiconductor die 50′ may include a second semiconductor substrate 51′, a second circuit region 52′, and second through vias 55′. A structure and materials of the first semiconductor die 50′ may be similar to or same as those of the first semiconductor die 40′.

The second semiconductor substrate 51′ may include a bulk semiconductor, a semiconductor-on-insulator (SOI) substrate, or the like. The second semiconductor substrate 51′ can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy.

The second circuit region 52′ may be disposed on the second semiconductor substrate 51′. The second circuit region 52′ may include one or more dielectric layers and integrated circuits (ICs) at least partially embedded in one or more dielectric layers. The second circuit region 52′ may include a second memory control circuit 53′ and a second cache memory 54′.

The second memory control circuit 53′ may be disposed on the second semiconductor substrate 51′. The second memory control circuit 53′ may be disposed within the second circuit region 52′. The second memory control circuit 53′ may receive signals from the second cache memory 54′, the electronic component 70′, the electronic component 82′, and/or other components. The second memory control circuit 53′ may be configured to manage and process data transmitted between the electronic component 70′ and other circuits (e.g., the cache memory 54′, the electronic component 82′, and/or other ICs) operating according to a different communication standard. The second memory control circuit 53′ may include various memory controllers, for example, devices which may control IDE (integrated device electronics), a SATA (serial advanced technology attachment), an SCSI (small computer system interface), a RAID (redundant array of independent disks), an SSD (solid state disk), an eSATA (external SATA), a PCMCIA (Personal Computer Memory Card International Association) card (also known as a PC card), a USB (universal serial bus), a secure digital (SD) card, a mini secure digital (mini SD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The second cache memory 54′ may be disposed on the second semiconductor substrate 51′. The second cache memory 54′ may be disposed within the second circuit region 52′. In some embodiments, the second memory control circuit 53′ may be in communication with the second cache memory 54′. In some embodiments, the second cache memory 54′ may be configured to temporarily store data (e.g., a signal from the electronic component 70′). In some embodiments, the second cache memory 54′ may be configured to compensate for a difference between data processing speeds of the electronic component 70′ operating at a high speed and an external device (not shown) operating at a low speed. In some embodiments, the second cache memory 54′ may be configured to store data for performing an operation, data corresponding to a result of an operation, or an address of data for which an operation is performed. In some embodiments, the second cache memory 54′ may include an SRAM or other suitable memories.

In some embodiments, the second through via 55′ may penetrate the second semiconductor substrate 51′. In some embodiments, the second through via 55′ may be disposed between the second circuit region 52′ and the redistribution structure 21′. In some embodiments, the second through via 55′ may be disposed between the second memory control circuit 53′ and the redistribution structure 21′. In some embodiments, the second through via 55′ may be disposed between the second cache memory 54′ and the redistribution structure 21′. In some embodiments, the second through via 55′ may be electrically connected to the second memory control circuit 53′. In some embodiments, the second through via 55′ may be electrically connected to the second cache memory 54′. In some embodiments, the second through via 55′ may include a through-silicon via (TSV). In some embodiments, the second through via 55′ may include copper, aluminum, titanium, another conductive metal, or an alloy thereof.

As shown in FIG. 2B, in some embodiments, an air gap structure 513′ may be disposed between two adjacent through vias 55′. In some embodiments, the air gap structure 513′ may be disposed between two adjacent through vias 55′ under the cache memory 54′. In some embodiments, the air gap structure 513′ includes an air gap 511C and a liner 511B′, wherein the air gap 511C′ is enclosed by the liner 511B′.

As shown in FIG. 2C, in some embodiments, the second through via 55′ includes a first block 552′ having a uniform first critical dimension CD1′, a second block 554′ having a uniform second critical dimension CD2′ different from the first critical dimension CD1′, and a third block 556′ having a varying third critical dimension CD3′, wherein the third block 556′ connects the second block 554′ to the first block 552′. In particular, the first critical dimension CD1′ is less than the second critical dimension CD2′, and the third critical dimension CD3′ gradually increases at positions of increasing distance from the first block 552′, and gradually decreases at positions of increasing distance from the second block 554′. As a result, the first and second blocks 552′ and 554′ have vertical peripheral surfaces 5522′ and 5542′, and the third block 556′ has an inclined peripheral surface 5562′.

In some embodiments, the first block 552′ of the second through via 55′ has a first height H1′. In addition, the second block 554′ of the second through via 55′ has a second height H2′ greater than the first height H1′, and the third block 556′ of the second through via 55′ has a third height H3′ less than the first height H1′. In some embodiments, the first height H1′ is greater than 1 μm.

The non-uniform critical dimension of the second through via 55′ may increase utilization of the second semiconductor substrate 51′. In some embodiments, the second through via 55′ can be provided using a via-last process.

In some embodiments, the first cache memory 44′ of the first semiconductor die 40′ may be closer to the second memory control circuit 53′ than to the second cache memory 54′. In some embodiments, the second memory control circuit 53′ may be disposed between the first cache memory 44′ and the second cache memory 54′.

In some embodiments, the interposer 30′ may further include an encapsulant 60′. In some embodiments, the encapsulant 60′ may encapsulate the first semiconductor die 40′. In some embodiments, the encapsulant 60′ may encapsulate the second semiconductor die 50′. In some embodiments, the encapsulant 60′ may be disposed between the redistribution structures 21′ and 22′. In some embodiments, the encapsulant 60′ may be in contact with the redistribution structure 21′. In some embodiments, the encapsulant 60′ may be in contact with the redistribution structure 22′. In some embodiments, a bottom surface (not indicated in FIG. 2C) of the encapsulant 60′ may be substantially coplanar with a bottom surface (not indicated in FIG. 2C) of the first semiconductor die 40′. In some embodiments, the bottom surface of the encapsulant 60′ may be substantially coplanar with a bottom surface (not indicated in FIG. 2C) of the second semiconductor die 50′. In some embodiments, the encapsulant 60′ includes, for example, organic materials (e.g., a molding compound, bismaleimide triazine (BT), polyimide (PI), polybenzoxazole (PBO), a solder resist, an ABF, polypropylene (PP) or an epoxy-based material), inorganic materials (e.g., silicon, glass, ceramic or quartz), liquid and/or dry-film materials or a combination thereof. Suitable fillers may also be included, such as powdered SiO₂.

In some embodiments, the redistribution structure 22′ may be disposed on the surface 30s2′ of the interposer 30′. The redistribution structure 22′ may include one or more dielectric layers, one or more conductive traces, and one or more conductive vias (not shown). The dielectric layer may include an insulating material, a passivation material, a dielectric material or a solder resist material, such as, for example, a benzocyclobutene (BCB) based polymer or polyimide (PI). The dielectric layer may be made of a photoimageable material. The conductive trace may be disposed on or over a surface (e.g., a top surface or a bottom surface) of the dielectric layer. The conductive via may be disposed on or over a surface (e.g., a top surface or a bottom surface) of the conductive trace. Materials of the conductive trace and the conductive via may include, for example, copper, aluminum, titanium, another conductive metal, or an alloy thereof. In some embodiments, a dimension (e.g., width, surface area, and/or aperture) of the conductive trace (or the conductive via) within the redistribution structure 22′ may be less than such dimension of the conductive trace (or the conductive via) within the carrier 10′. In some embodiments, a lateral surface of the redistribution structure 22′ may be aligned with a lateral surface of the redistribution structure 21′. In some embodiments, the lateral surface of the redistribution structure 22′ may be aligned the lateral surface of the interposer 30′. In some embodiments, the lateral surface of the redistribution structure 22′ may be aligned with a lateral surface of the encapsulant 60′.

In some embodiments, the electronic component 70′ may be disposed on the surface 30s2′ of the interposer 30′. In some embodiments, the electronic component 70′ may be disposed on the redistribution structure 22′. In some embodiments, the electronic component 70′ may be spaced apart from the interposer 30′ by the redistribution structure 22′. In some embodiments, the electronic component 70′ may vertically overlap the first cache memory 44′. In some embodiments, the electronic component 70′ may vertically overlap the second memory control circuit 53′. In some embodiments, the electronic component 70′ may be free from vertically overlapping the first memory control circuit 43′. In some embodiments, the electronic component 70′ may be free from vertically overlapping the second cache memory 54′. In some embodiments, the electronic component 70′ may be electrically connected to or in communication with the first memory control circuit 43′ via the redistribution structure 22′. In some embodiments, the electronic component 70′ may be electrically connected to or in communication with the first cache memory 44′ via the redistribution structure 22′. In some embodiments, the electronic component 70′ may be electrically connected to or in communication with the second memory control circuit 53′ via the redistribution structure 22′. In some embodiments, the electronic component 70′ may be electrically connected to or in communication with the second cache memory 54′ via the redistribution structure 22′. In some embodiments, the electronic component 70′ may be electrically connected to or in communication with the cache memories 44′ and 54′ via the redistribution structure 22′. In some embodiments, the electronic component 70′ may include logic circuits and/or other suitable circuits. In some embodiments, the electronic component 70′ may include a central processing unit (CPU), a microprocessor unit (MPU), a graphics processing unit (GPU), a microcontroller unit (MCU), a field-programmable gate array (FPGA), an application processor (AP) or another type of IC. In some embodiments, the electronic component 70′ does not include a cache memory.

In some embodiments, the electronic component 81′ may be disposed on the surface 30s2′ of the interposer 30′. In some embodiments, the electronic component 81′ may be disposed on the redistribution structure 22′. In some embodiments, the electronic component 81′ may be spaced apart from the interposer 30′ by the redistribution structure 22′. In some embodiments, the electronic component 81′ may vertically overlap the first memory control circuit 43′. In some embodiments, the electronic component 81′ may be free from vertically overlapping the first cache memory 44′. In some embodiments, the electronic component 81′ may be electrically connected to or in communication with the electronic component 70′ via the redistribution structure 22′. In some embodiments, the electronic component 81′ may be electrically connected to or in communication with the first memory control circuit 43′ via the redistribution structure 22′. In some embodiments, the electronic component 81′ may include a dynamic random-access memory (DRAM). For example, the electronic component 81′ may include at least a transistor(s), at least a capacitor(s), and/or other suitable elements. In some embodiments, the electronic component 81′ may include a high bandwidth memory (HBM).

In some embodiments, the electronic component 82′ may be disposed on the surface 30s2′ of the interposer 30′. In some embodiments, the electronic component 82′ may be disposed on the redistribution structure 22′. In some embodiments, the electronic component 82′ may be spaced apart from the interposer 30′ by the redistribution structure 22′. In some embodiments, the electronic component 82′ may vertically overlap the second cache memory 54′. In some embodiments, the electronic component 82′ may be free from vertically overlapping the second memory control circuit 53′. In some embodiments, the electronic component 82′ may be electrically connected to or in communication with the electronic component 70′ via the redistribution structure 22′. In some embodiments, the electronic component 82′ may be electrically connected to or in communication with the second memory control circuit 53′ via the redistribution structure 22′. In some embodiments, the electronic component 82′ may include a DRAM. For example, the electronic component 82′ may include at least a transistor, at least a capacitor, and/or other suitable elements. In some embodiments, the electronic component 82′ may include an HBM.

In a comparative example, the logic circuits and cache memories are integrated as a die, which increases a size of the die and adversely affects miniaturization of a semiconductor device structure. In the embodiments of the present disclosure, the semiconductor device structure includes an electronic component and a semiconductor die. The logic circuits are disposed within the electronic component (e.g., the electronic component 70′) and the cache memories are disposed within the semiconductor die (e.g., the first semiconductor die 40′ and/or the second semiconductor die 50′). Therefore, the size of the electronic component is reduced, which thereby assists in the miniaturization of the semiconductor device structure. Further, the cache memories may include at least two portions disposed within two semiconductor dies. As a result, the logic circuits may be in communication with one or more semiconductor dies according to requirements. Further, such design may improve a manufacturing yield of the semiconductor device structure.

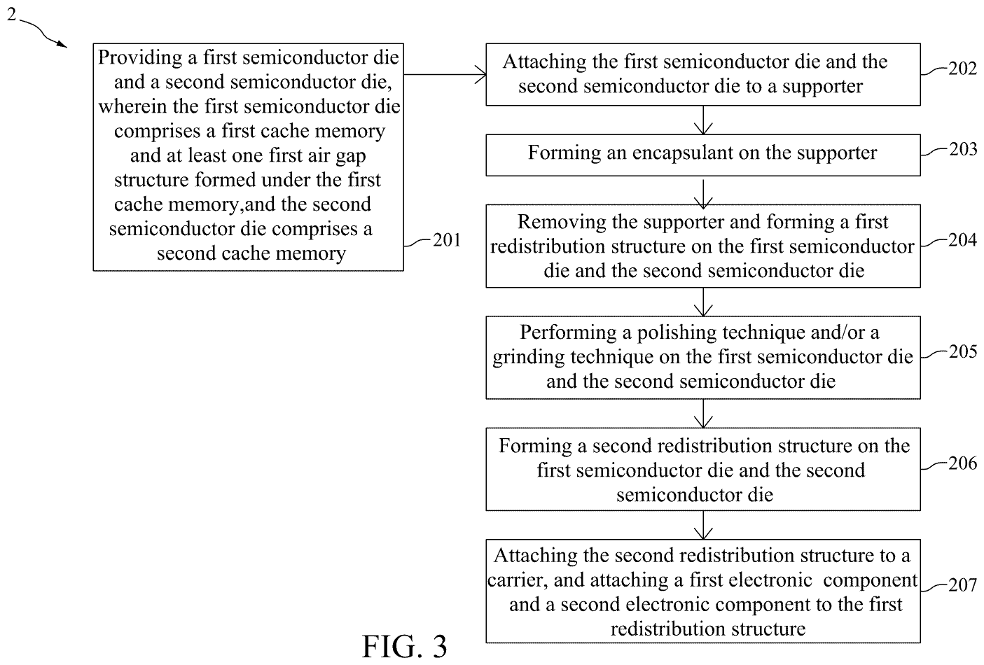

FIG. 3 is a flowchart illustrating a method 2 of manufacturing a semiconductor device structure, in accordance with some embodiments of the present disclosure.

The method 2 begins with operation 201, in which a first semiconductor die and a second semiconductor die may be provided. The first semiconductor die may have a bottom surface and a top surface opposite to the bottom surface. The first semiconductor die may include a first semiconductor substrate, a first circuit region, and first through vias. The first circuit region may include a first memory control circuit and a first cache memory. The first memory control circuit may be located adjacent to the top surface of the first semiconductor die. The first cache memory may be located adjacent to the top surface of the first semiconductor die. The first through via may penetrate a portion of the first semiconductor substrate. The second semiconductor die may have a bottom surface and a top surface opposite to the bottom surface. The second semiconductor die may include a second semiconductor substrate, a second circuit region, and second through vias. The second circuit region may include a second memory control circuit and a second cache memory. The second memory control circuit may be located adjacent to the top surface of the second semiconductor die. The second cache memory may be located adjacent to the top surface of the second semiconductor die. The second through via may penetrate a portion of the second semiconductor substrate. The first semiconductor die may further include a first air gap structure, which is disposed between two adjacent first through vias under the first cache memory. The first air gap structure may include an air gap and a liner, and the air gap may be enclosed by the liner. The second semiconductor die may further include a second air gap structure, which is disposed between two adjacent second through vias under the second cache memory. The second air gap structure may include an air gap and a liner, and the air gap may be enclosed by the liner.

The method 2 continues with operation 202, in which the first semiconductor die and the second semiconductor die may be attached to a supporter. The top surface of the first semiconductor die may be attached to the supporter. The top surface of the second semiconductor die may be attached to the supporter.

The method 2 continues with operation 203, in which an encapsulant may be formed on the supporter. The encapsulant may encapsulate the first semiconductor die. The encapsulant may encapsulate the second semiconductor die.

The method 2 continues with operation 204, in which the supporter may be removed from the first semiconductor die and the second semiconductor die. A first redistribution structure may be formed on the top surface of the first semiconductor die. The first redistribution structure may be formed on the top surface of the second semiconductor die. The first redistribution structure may be formed on a top surface of the encapsulant.

The method 2 continues with operation 205, in which a polishing technique and/or a grinding technique may be performed on the bottom surface of the first semiconductor die and on the bottom surface of the second semiconductor die. A portion of the first semiconductor substrate may be removed. A portion of the second semiconductor substrate may be removed. The first through via may be exposed through the bottom surface of the first semiconductor die. The second through via may be exposed through the bottom surface of the second semiconductor die. As a result, an interposer, including the first semiconductor die and the second semiconductor die, may be produced.

The method 2 continues with operation 206, in which a second redistribution structure may be formed on the bottom surface of the first semiconductor die. The second redistribution structure may be formed on the bottom surface of the second semiconductor die. The second redistribution structure may be formed on the bottom surface of the encapsulant.

The method 2 continues with operation 207, in which the second redistribution structure may be attached to a carrier. A first electronic component (e.g., a logic circuit) may be attached to the first redistribution structure. A second electronic component (e.g., a DRAM) may be attached to the first redistribution structure. As a result, a semiconductor device structure may be produced.

The method 2 is merely an example, and is not intended to limit the present disclosure beyond what is explicitly recited in the claims. Additional operations can be provided before, during, or after each operation of the method 2, and some operations described can be replaced, eliminated, or reordered for additional embodiments of the method. In some embodiments, the method 2 can include further operations not depicted in FIG. 3. In some embodiments, the method 2 can include one or more operations depicted in FIG. 3.

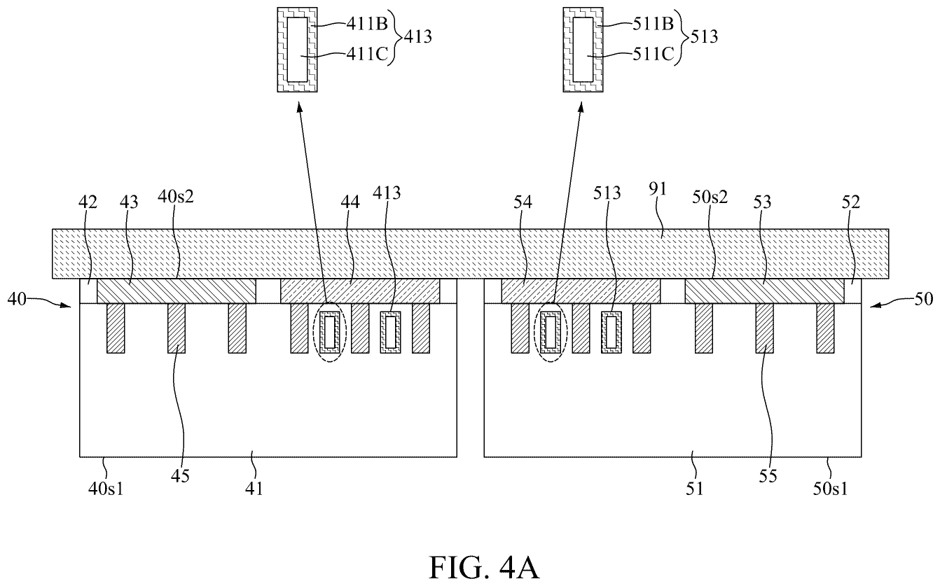

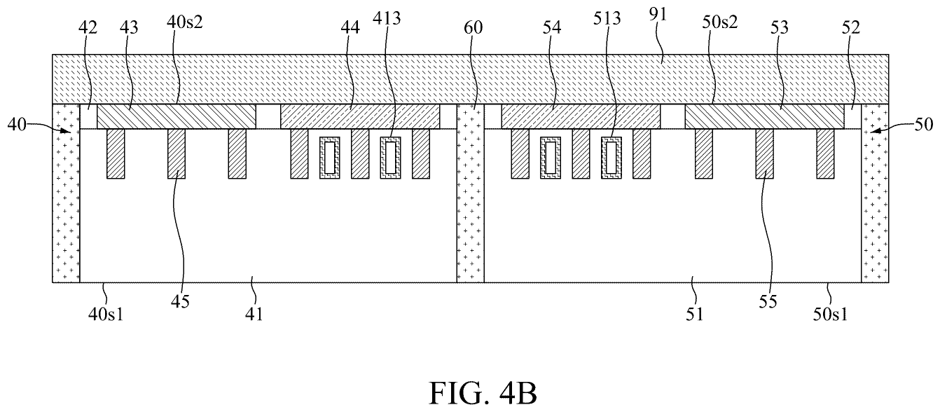

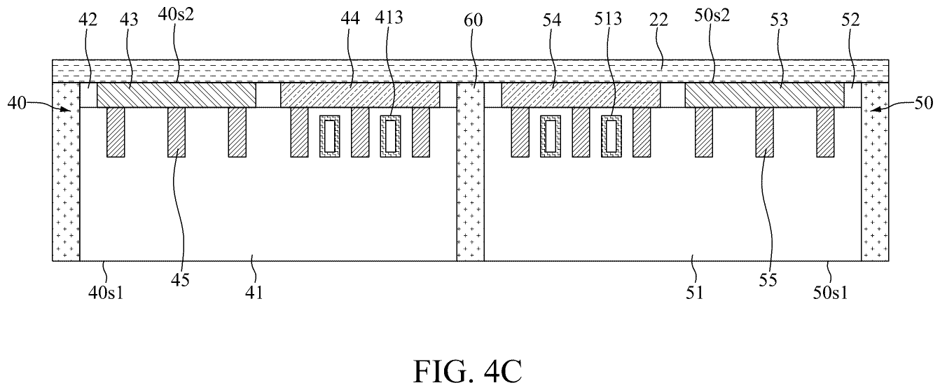

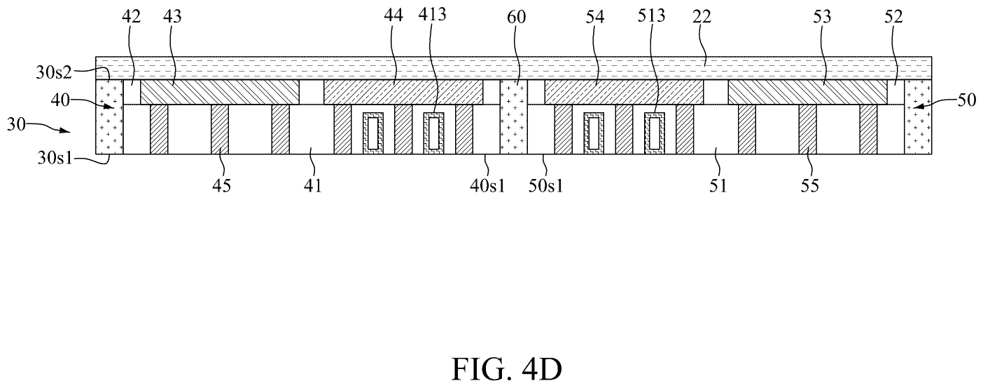

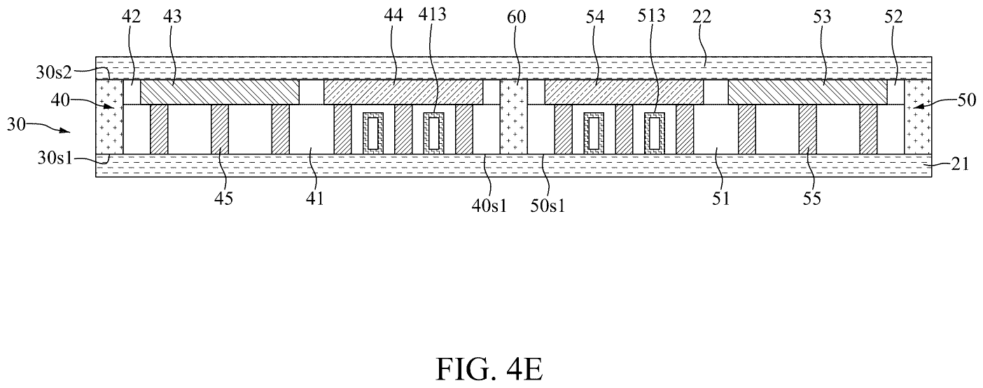

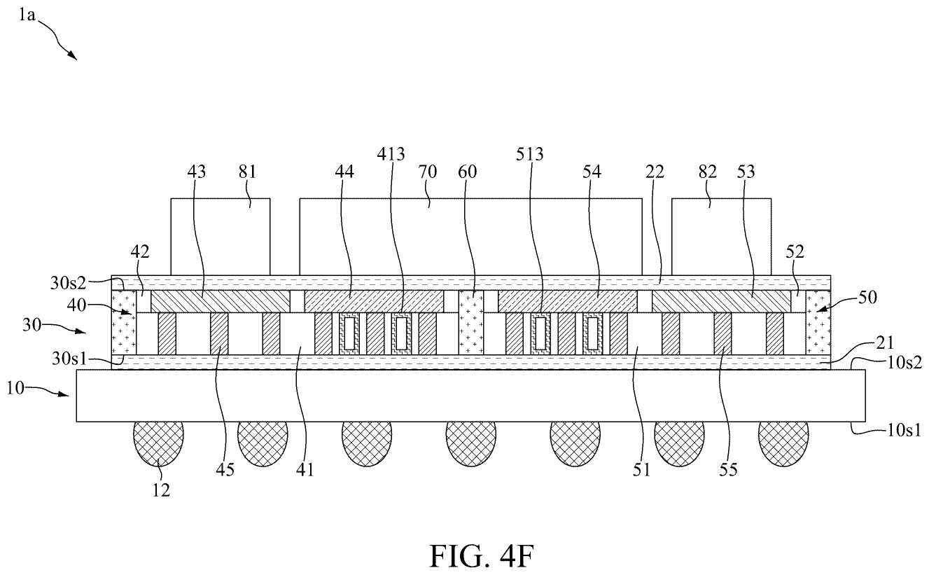

FIGS. 4A to 4F illustrate one or more stages of an exemplary method of manufacturing a semiconductor device structure according to some embodiments of the present disclosure.

As shown in FIG. 4A, a plurality of first through vias 45 are formed in a spaced-apart array in a first semiconductor substrate 41, and a plurality of second through vias 55 are formed in a spaced-apart array in a second semiconductor substrate 51. In some embodiments, a first space 41A1 is formed between two adjacent first through vias 45 in a portion of the first semiconductor substrate 41, and a second space 51A1 is formed between two adjacent second through vias 55 in a portion of the second semiconductor substrate 51.

In some embodiments, A first air gap structure 413 including an air gap 411C enclosed by a liner 411B is formed between the adjacent first through vias 45, and A second air gap structure 513 is formed between the adjacent second through vias 55. A top surface of the first air gap structure 413 is lower than top surfaces of the first through vias 45, and a top surface of the second air gap structure 513 is lower than top surfaces of the second through vias 55.

It should be noted that an air gap structure (i.e., the first air gap structure 413 and the second air gap structure 513) is formed under a cache memory (i.e., a first cache memory 44 or a second cache memory 54), which is described below, while no air gap structure exists under a memory control circuit (i.e., a first memory control circuit 43 or a second memory control circuit 53), which is described below.

A first semiconductor die 40 and a second semiconductor die 50 may be provided. The first semiconductor die 40 may have a surface 40s1 and a surface 40s2 opposite to the surface 40s1. The first semiconductor die 40 may include the first semiconductor substrate 41, a first circuit region 42, the first through vias 45 and the first air gap structures 413. The first circuit region 42 is a dielectric layer, and the first circuit region 42 may include the first memory control circuit 43 and the first cache memory 44. The first memory control circuit 43 may be located adjacent to the surface 40s2. The first cache memory 44 may be located adjacent to the surface 40s2. The first through via 45 may penetrate a portion of the first semiconductor substrate 41 and extend from the surface 40s2. The first air gap structure 413 is formed in the first semiconductor substrate 41, between adjacent first through vias 45 under the first cache memory 44. The second semiconductor die 50 may have a surface 50s1 and a surface 50s2 opposite to the surface 50s1. The second semiconductor die 50 may include a second semiconductor substrate 51, a second circuit region 52, the second through vias 55, and the second air gap structures 513. The second circuit region 52 may include the second memory control circuit 53 and the second cache memory 54. The second memory control circuit 53 may be located adjacent to the surface 50s2. The second cache memory 54 may be located adjacent to the surface 50s2. The second through via 55 may penetrate a portion of the second semiconductor substrate 51 and extend from the surface 50s2. The second air gap structure 513 is formed in the second semiconductor substrate 51, between adjacent second through vias 55 under the second cache memory 54.

The first semiconductor die 40 and the second semiconductor die 50 may be attached to a supporter 91. In some embodiments, the supporter 91 may include a glass carrier, a ceramic carrier, a plastic carrier, or another suitable carrier. The surface 40s2 of the first semiconductor die 40 may be attached to the supporter 91. The surface 50s2 of the second semiconductor die 50 may be attached to the supporter 91. The respective step is illustrated as the operations 201 and 202 in the method 2 shown in FIG. 3.

As shown in FIG. 4B, an encapsulant 60 may be formed on the supporter 91. The encapsulant 60 may encapsulate the first semiconductor die 40. The encapsulant 60 may encapsulate the second semiconductor die 50. The respective step is illustrated as the operation 203 in the method 2 shown in FIG. 3.

As shown in FIG. 4C, the supporter 91 may be removed from the first semiconductor die 40 and the second semiconductor die 50. A redistribution structure 22 may be formed on the surface 40s2 of the first semiconductor die 40. The redistribution structure 22 may be formed on the surface 50s2 of the second semiconductor die 50. The redistribution structure 22 may be formed on a top surface of the encapsulant 60. That is, the redistribution structure 22 may cover the surface 40s2 of the first semiconductor die 40, the surface 50s2 of the second semiconductor die 50, and the top surface of the encapsulant 60. The respective step is illustrated as the operation 204 in the method 2 shown in FIG. 3.

As shown in FIG. 4D, a polishing technique and/or a grinding technique may be performed on the surface 40s1 of the first semiconductor die 40 and the surface 50s1 of the second semiconductor die 50. A portion of the first semiconductor substrate 41 may be removed. A portion of the second semiconductor substrate 51 may be removed. The first through via 45 may be exposed through the surface 40s1 of the first semiconductor die 40. The second through via 55 may be exposed through the surface 50s2 of the second semiconductor die 50. As a result, an interposer 30, including the first semiconductor die 40 and the second semiconductor die 50, may be produced. The respective step is illustrated as the operation 205 in the method 2 shown in FIG. 3.

As shown in FIG. 4E, a redistribution structure 21 may be formed on the surface 40s1 of the first semiconductor die 40. The redistribution structure 21 may be formed on the surface 50s1 of the second semiconductor die 50. The redistribution structure 21 may be formed on the bottom surface of the encapsulant 60. That is, the redistribution structure 21 may cover the surface 40s1 of the first semiconductor die 40, the surface 50s1 of the second semiconductor die 50, and the bottom surface of the encapsulant 60. The respective step is illustrated as the operation 206 in the method 2 shown in FIG. 3.

As shown in FIG. 4F, the redistribution structure 21 may be attached to a carrier 10. An electronic component 70 may be attached to the redistribution structure 22. Electronic components 81 and 82 may be attached to the redistribution structure 22. As a result, a semiconductor device structure, such as the semiconductor device structure 1a as shown in FIG. 1A and FIG. 1B, may be produced. The respective step is illustrated as the operation 207 in the method 2 shown in FIG. 3.

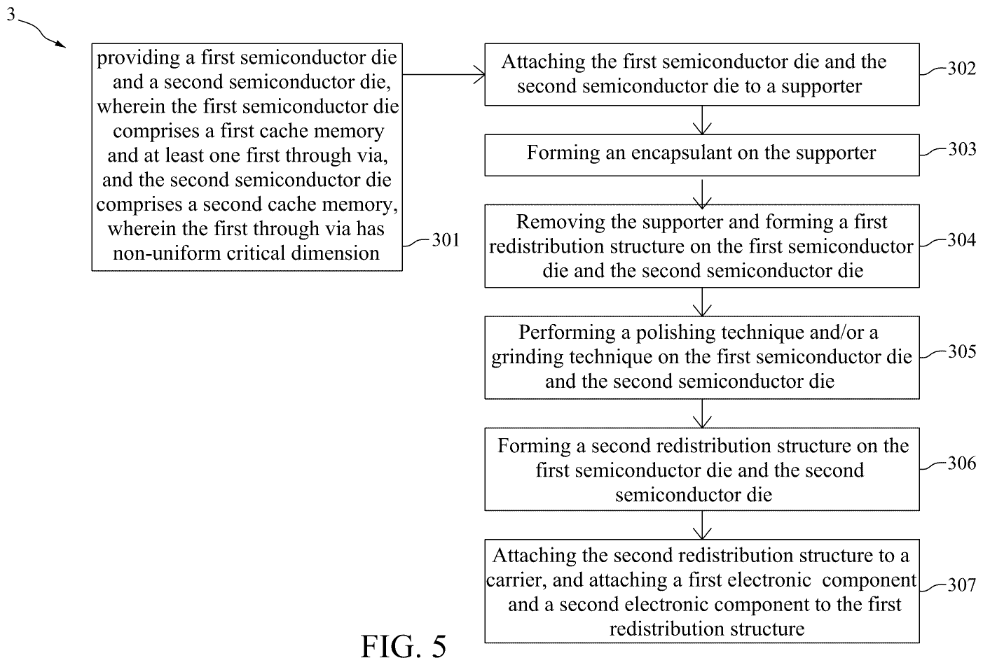

FIG. 5 is a flowchart illustrating a method 3 of manufacturing a semiconductor device structure, in accordance with other embodiments of the present disclosure.

The method 3 begins with operation 301, in which a first semiconductor die and a second semiconductor die may be provided. The first semiconductor die may have a bottom surface and a top surface opposite to the bottom surface. The first semiconductor die may include a first semiconductor substrate, a first circuit region, and first through vias. The first circuit region may include a first memory control circuit and a first cache memory. The first memory control circuit may be located adjacent to the top surface of the first semiconductor die. The first cache memory may be located adjacent to the top surface of the first semiconductor die. The first through via may penetrate a portion of the first semiconductor substrate. The second semiconductor die may have a bottom surface and a top surface opposite to the bottom surface. The second semiconductor die may include a second semiconductor substrate, a second circuit region, and second through vias. The second circuit region may include a second memory control circuit and a second cache memory. The second memory control circuit may be located adjacent to the top surface of the second semiconductor die. The second cache memory may be located adjacent to the top surface of the second semiconductor die. The second through via may penetrate a portion of the second semiconductor substrate.

In some embodiments, the first through via includes a first block having a uniform first critical dimension, a second block having a uniform second critical dimension different from the first critical dimension, and a third block having a varying third critical dimension, wherein the third block connects the second block to the first block. In particular, the first critical dimension is less than the second critical dimension, and the third critical dimension gradually increases at positions of increasing distance from the first block, and gradually decreases at positions of increasing distance from the second block. As a result, the first block and the second block have vertical peripheral surfaces, and the third block has an inclined peripheral surface. In some embodiments, the first block of the first through via has a first height. In addition, the second block of the first through via has a second height greater than the first height, and the third block of the through via has a third height less than the first height. For example, the first height is greater than 1 μm.

The non-uniform critical dimension of the first through via may increase utilization of the first semiconductor substrate. In some embodiments, the first through via can be provided using a via-last process.

In some embodiments, the second through via includes a first block having a uniform first critical dimension, a second block having a uniform second critical dimension different from the first critical dimension, and a third block having a varying third critical dimension, wherein the third block connects the second block to the first block. In particular, the first critical dimension is less than the second critical dimension, and the third critical dimension gradually increases at positions of increasing distance from the first block, and gradually decreases at positions of increasing distance from the second block. As a result, the first block and the second block have a vertical peripheral surface respectively, and the third block has an inclined peripheral surface. In some embodiments, the first block of the second through via has a first height. In addition, the second block of the second through via has a second height greater than the first height, and the third block of the second through via has a third height less than the first height. In some embodiments, the first height is greater than 1 μm.

The non-uniform critical dimension of the second through via may increase utilization of the second semiconductor substrate. In some embodiments, the second through via can be provided using a via-last process.

The method 3 continues with operation 302, in which the first semiconductor die and the second semiconductor die may be attached to a supporter. The top surface of the first semiconductor die may be attached to the supporter. The top surface of the second semiconductor die may be attached to the supporter.

The method 3 continues with operation 303, in which an encapsulant may be formed on the supporter. The encapsulant may encapsulate the first semiconductor die. The encapsulant may encapsulate the second semiconductor die.

The method 3 continues with operation 304, in which the supporter may be removed from the first semiconductor die and the second semiconductor die. A first redistribution structure may be formed on the top surface of the first semiconductor die. The first redistribution structure may be formed on the top surface of the second semiconductor die. The first redistribution structure may be formed on a top surface of the encapsulant.

The method 3 continues with operation 305, in which a polishing technique and/or a grinding technique may be performed on the bottom surface of the first semiconductor die and on the bottom surface of the second semiconductor die. A portion of the first semiconductor substrate may be removed. A portion of the second semiconductor substrate may be removed. The first through via may be exposed through the bottom surface of the first semiconductor die. The second through via may be exposed through the bottom surface of the second semiconductor die. As a result, an interposer, including the first semiconductor die and the second semiconductor die, may be produced.

The method 3 continues with operation 306, in which a second redistribution structure may be formed on the bottom surface of the first semiconductor die. The second redistribution structure may be formed on the bottom surface of the second semiconductor die. The second redistribution structure may be formed on the bottom surface of the encapsulant.

The method 3 continues with operation 307, in which the second redistribution structure may be attached to a carrier. A first electronic component (e.g., a logic circuit) may be attached to the first redistribution structure. A second electronic component (e.g., a DRAM) may be attached to the first redistribution structure. As a result, a semiconductor device structure may be produced.

The method 3 is merely an example, and is not intended to limit the present disclosure beyond what is explicitly recited in the claims. Additional operations can be provided before, during, or after each operation of the method 3, and some operations described can be replaced, eliminated, or reordered for additional embodiments of the method. In some embodiments, the method 3 can include further operations not depicted in FIG. 5. In some embodiments, the method 3 can include one or more operations depicted in FIG. 5.

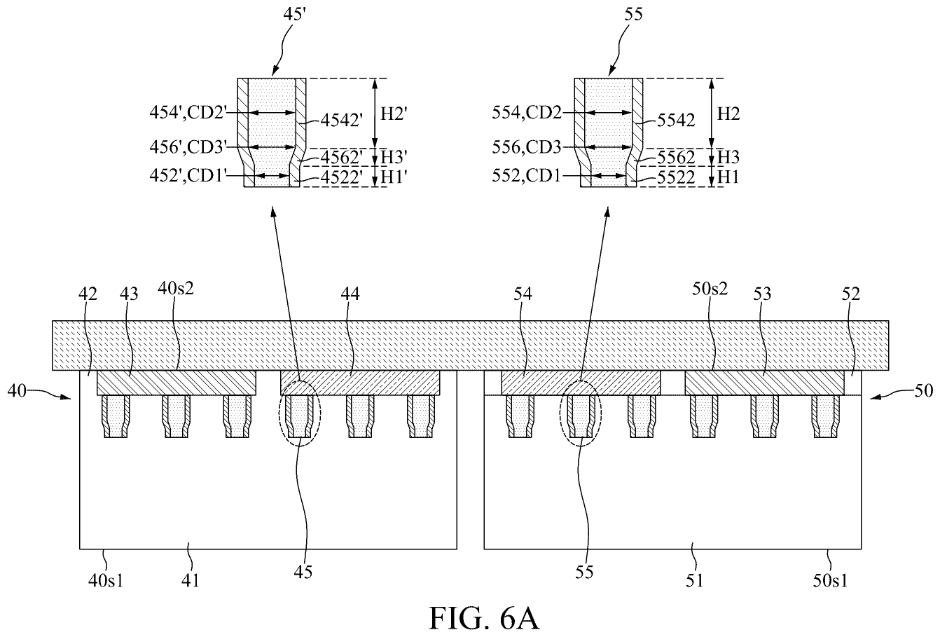

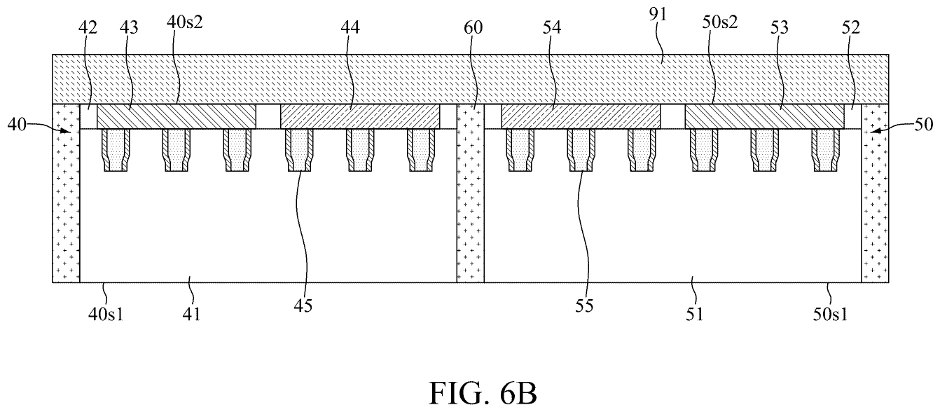

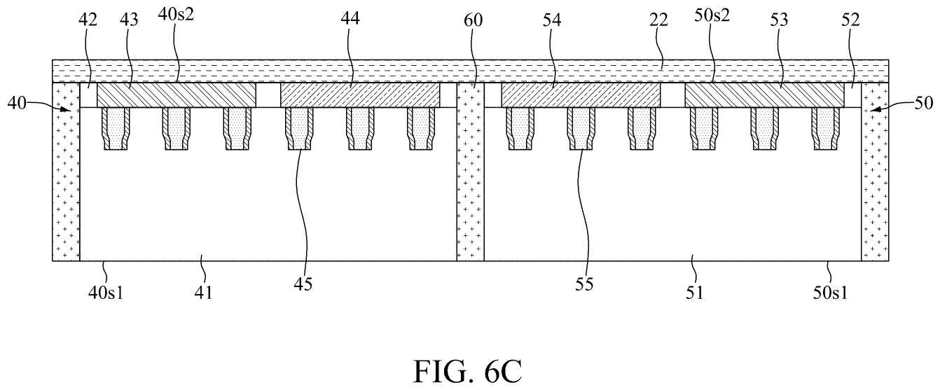

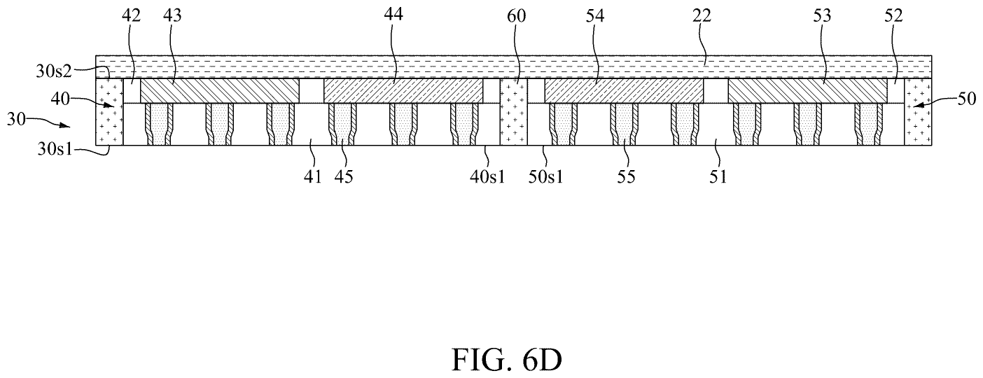

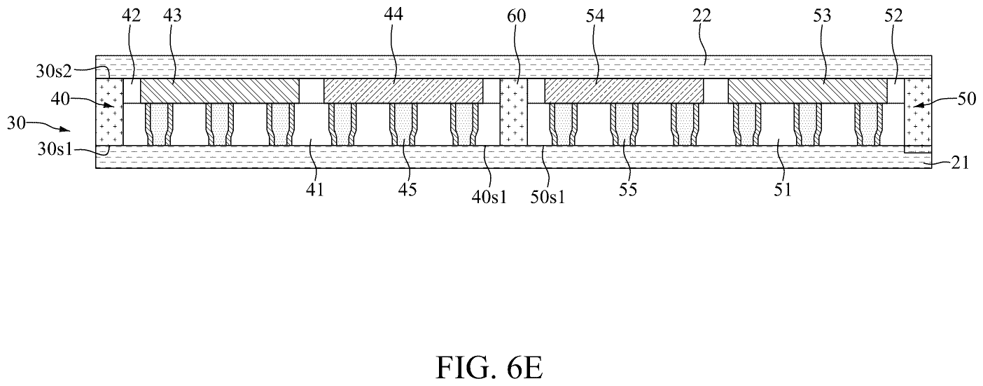

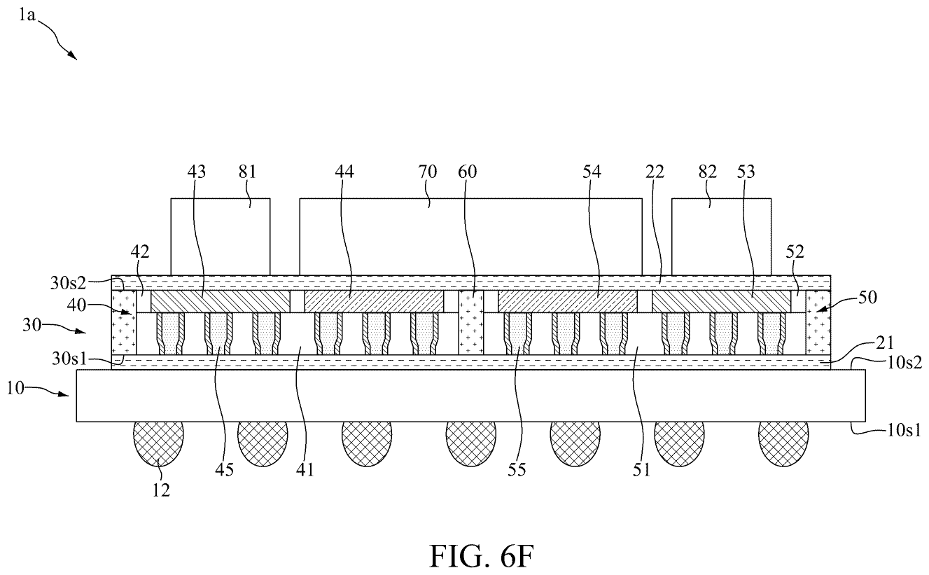

FIGS. 6A to 6F illustrate one or more stages of an exemplary method 3 of manufacturing a semiconductor device structure according to some embodiments of the present disclosure. The operations 302 to 307 of the method 3 are same as the operations 202 to 207 of the method 2, and further description in detail will not be provided herein below.

As shown in FIG. 6A, a first semiconductor substrate 41 and a second semiconductor substrate 51 are provided, and are similar to the semiconductor substrates 41 and 51 in FIG. 4A. Because the configurations of the first semiconductor substrate 41 and the second semiconductor substrate 51 are the same, the operations below are described with reference to only the first semiconductor substrate 41, although, in some configuration, the operations are performed on both the first and second semiconductor substrates 41 and 51.

As shown in FIG. 6A, a structure of FIG. 6A is similar to a structure of FIG. 4A, except to the structure of FIG. 6A has different through vias and has no air gap structures. The numeral of through vias is the same as FIG. 4A. In some embodiments, the first through via 45 of FIG. 6A includes a first block 452 having a uniform first critical dimension CD1, a second block 454 having a uniform second critical dimension CD2 different from the first critical dimension CD1, and a third block 456 having a varying third critical dimension CD3, wherein the third block 456 connects the second block 454 to the first block 452. In particular, the first critical dimension CD1 is less than the second critical dimension CD2, and the third critical dimension CD3 gradually increases at positions of increasing distance from the first block 452, and gradually decreases at positions of increasing distance from the second block 454. As a result, the first and second blocks 452 and 454 have vertical peripheral surfaces 4522 and 4542, respectively, and the third block 456 has an inclined peripheral surface 4562.

In some embodiments, the first block 452 of the first through via 45 has a first height H1. In addition, the second block 454 of the first through via 45 has a second height H2 greater than the first height H1, and the third block 456 of the first through via 45 has a third height H3 less than the first height H1. In some embodiments, the first height H1 is greater than 1 μm.

The non-uniform critical dimension of the first through via 45 may increase utilization of the first semiconductor substrate 41. In some embodiments, the first through via 45 can be provided using a via-last process.

In some embodiments, a plurality of first through vias 45 is formed in the first semiconductor substrate 41, and a plurality of second through vias 55 is formed in the second semiconductor substrate 51.

As shown in FIG. 6A, in operation 301 of the method 3, a first semiconductor die 40 is provided with the first through vias 45 having non-uniform critical dimensions, and a second semiconductor die 50 is provided with the second through vias 55 having non-uniform critical dimensions, wherein the second through vias 55 are similar to or same as the first through vias 45. The first semiconductor die 40 and the second semiconductor die 50 formed by the method 3 are similar to or same as the first semiconductor die 40 and the second semiconductor die 50 formed by the method 2, except the first semiconductor die 40 and the second semiconductor die 50 formed by the method 3 have no air gap structures, and the first semiconductor die 40 and the second semiconductor die 50 formed by the method 3 include the first through vias 45 having non-uniform critical dimensions and the second through vias 55 having non-uniform critical dimensions, respectively. The respective step is illustrated as the operation 301 and 302 in the method 3 shown in FIG. 5. The following operations 302 to 307 of the method 3 corresponding to FIGS. 6B to 6F respectively are similar to and the same as operations 202 to 207 of the method 2 corresponding to FIGS. 4B to 4F respectively, and further description in detail will not be provided herein below.

One aspect of the present disclosure provides a semiconductor device structure. The semiconductor device structure includes an interposer and a first electronic component. The interposer includes a first semiconductor die and a second semiconductor die. The first semiconductor die includes a first cache memory and a first memory control circuit. The second semiconductor die includes a second cache memory and a second memory control circuit. The first electronic component is disposed on the interposer and is in communication with the first semiconductor die and the second semiconductor die. The first semiconductor die comprises at least one first air gap structure.

Another aspect of the present disclosure provides another semiconductor device structure. The semiconductor device structure includes an interposer and a first electronic component. The interposer includes a first semiconductor die and a second semiconductor die. The first semiconductor die includes a first cache memory and a first memory control circuit. The second semiconductor die includes a second cache memory and a second memory control circuit. The first electronic component is disposed on the interposer and is in communication with the first semiconductor die and the second semiconductor die. The first semiconductor die comprises at least one first through via extending from a first surface of the first semiconductor die. The first through via has non-uniform critical dimensions.

Another aspect of the present disclosure provides a method of manufacturing a semiconductor device structure. The method includes: providing a first semiconductor die and a second semiconductor die, wherein the first semiconductor die comprises a first cache memory and at least one first air gap structure formed under the first cache memory, and the second semiconductor die comprises a second cache memory; forming a first redistribution structure on the first semiconductor die and the second semiconductor die; and attaching a first electronic component to the first redistribution structure, wherein the first electronic component is in communication with the first cache memory, the second cache memory, or both via the first redistribution structure.

Another aspect of the present disclosure provides a method of manufacturing a semiconductor device structure. The method includes: providing a first semiconductor die and a second semiconductor die, wherein the first semiconductor die comprises a first cache memory and at least one first through via, and the second semiconductor die comprises a second cache memory, wherein the first through via has non-uniform critical dimensions; forming a first redistribution structure on the first semiconductor die and the second semiconductor die; and attaching a first electronic component to the first redistribution structure, wherein the first electronic component is in communication with the first cache memory, the second cache memory, or both via the first redistribution structure.

In some embodiments of the present disclosure, a semiconductor device structure includes an electronic component and a semiconductor die. A logic circuit and a cache memory are disposed within the electronic component and the semiconductor die, respectively. Therefore, a size of the electronic component is reduced, which facilitates miniaturization of the semiconductor device structure. Further, the cache memory may include at least two portions disposed within two semiconductor dies. As a result, the logic circuit may be in communication with one or more semiconductor dies according to requirements. Further, such design may improve a manufacturing yield of the semiconductor device structure.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device structure, comprising:
an interposer, comprising:
a first semiconductor die comprising a first cache memory and a first memory control circuit; and
a second semiconductor die comprising a second cache memory and a second memory control circuit; and
a first electronic component disposed on the interposer and in communication with the first semiconductor die and the second semiconductor die;
wherein the first semiconductor die comprises at least one first through via extending from a first surface of the first semiconductor die;
wherein the first through via has non-uniform critical dimensions.

2. The semiconductor device structure of claim 1, further comprising:
a redistribution structure disposed between the interposer and the first electronic component.

3. The semiconductor device structure of claim 2, further comprising:
a second electronic component disposed on the interposer, wherein the second electronic component is in communication with the first electronic component via the redistribution structure.

4. The semiconductor device structure of claim 3, wherein the second electronic component comprises a dynamic random-access memory (DRAM).

5. The semiconductor device structure of claim 4, wherein the first cache memory comprises a static random-access memory (SRAM).

6. The semiconductor device structure of claim 5, wherein the second cache memory comprises an SRAM.

7. The semiconductor device structure of claim 1, wherein a distance from the first cache memory to the second cache memory is less than a distance from the first memory control circuit to the second cache memory.

8. The semiconductor device structure of claim 1, wherein the first cache memory is closer to the second memory control circuit than to the second cache memory.

9. The semiconductor device structure of claim 1, further comprising:
an encapsulant encapsulating the first semiconductor die and the second semiconductor die.

10. The semiconductor device structure of claim 1, wherein the first semiconductor die has the first surface and a second surface opposite to the first surface and facing the first electronic component, wherein the first cache memory is disposed adjacent to the second surface of the first semiconductor die.

11. The semiconductor device structure of claim 1, wherein the first electronic component vertically overlaps the first cache memory and the second cache memory.

12. The semiconductor device structure of claim 1, wherein the first through via includes a first block having a uniform first critical dimension, a second block having a uniform second critical dimension different from the first critical dimension, and a third block having a varying third critical dimension, wherein the third block connects the second block to the first block.
